(19) United States
(12) Patent Application Publication
(10) Pub. No.: US 2024/0038924 A1
(43) Pub. Date: Feb. 1, 2024

(54) A TRANSPARENT THIN FILM ELECTROLUMINESCENT DISPLAY ELEMENT AND A METHOD

(71) Applicant: Lumineq Oy, Espoo (FI)

(72) Inventors: Mika Karhunen, Espoo (FI); Jukka Lammi, Espoo (FI); Pertti Malvaranta, Espoo (FI)

(21) Appl. No.: 18/245,858

(22) PCT Filed: Sep. 16, 2021
(86) PCT No.: PCT/FI2021/050614

§ 371 Date: Mar. 17, 2023

(30) Foreign Application Priority Data
Sep. 17, 2020 (FI) 20205896

(51) Int. Cl. H01L 33/00; H01L 33/20; H01L 33/26; H01L 33/62; H01L 33/40

(52) U.S. Cl. CPC H01L 33/0008; H01L 33/20; H01L 33/26; H01L 33/62; H01L 33/40; H01L 2933/0033

(57) ABSTRACT

The invention relates to a display element and to a manufacturing method. The display element comprises a first conductor layer having a first active conductor element and a second conductor layer having a second active conductor element. The display element comprises first and second dielectric layers and an emissive layer. The first conductor layer comprises a first active electrical lead connected to the first active conductor element and the second conductor layer comprises a first passive electrical lead separate from the second active conductor element. One or more first electrical through leads extend between the first active electrical lead and the first passive electrical lead through the first and second dielectric layers and the emissive layer.

### FIELD OF THE INVENTION

The present invention relates to a transparent thin film electroluminescent display element and more particularly to a transparent thin film electroluminescent display element according to preamble of claim 1. The present invention also relates to a method for manufacturing a transparent thin film electroluminescent display element and more particularly to a method according to preamble of claim 11.

### BACKGROUND OF THE INVENTION

Transparent thin film electroluminescent displays (TASEL) comprise a stacked layer structure comprising an emissive layer arranged between first and dielectric layers. The stacked structure further comprises a first conductor layer arranged on the first dielectric layer such that the first dielectric layer is superposed between the emissive layer and the first conductor layer. The stacked structure also comprises a second conductive layer arranged on the second dielectric layer such that the second dielectric layer is superposed between the emissive layer and the second conductor layer. The first conductor layer comprises one or more first active conductor elements and the second conductor layer comprises one or more second conductor elements. The first conductor layer further comprises one or more first active electrical leads connected to the one or more first active conductor elements for providing electrical connection to the one or more first active conductor elements. The second conductor layer further comprises one or more second active electrical leads connected to the one or more second active conductor elements for providing electrical connection to the one or more second active conductor elements. The display or display element comprises emissive area or emissive areas where the one or more first active conductor elements and the one or more second active conductor elements are superposed. The emissive layer is arranged to emit light in the emissive area or emissive areas when electrical current flows through the emissive layer between the superposed one or more first active conductor elements and one or more second active conductor elements. The first active electrical leads in the first conductor layer and the second active electrical leads in the second conductor layer are not superposed in the stacked structure, but are provided on different areas of the display element. These conductor areas form border area(s) or non-emissive area(s) of the display element.

The first and second conductor layers and thus the first and second conductor elements are usually made of indium tin oxide (ITO). Further, also the first and second active electrical leads are made of ITO. ITO has high resistivity and may cause significant heat generation. Further, the high resistivity of ITO in the active electrical leads cause energy loss and voltage drop along the electrical leads and has negative effect on brightness of the display element.

In the prior art, this problem has been solved by utilizing thicker ITO layers in the first conductor layer in the active electrical leads. However, thicker ITO layers have negative effect on the transparency.

### BRIEF DESCRIPTION OF THE INVENTION

An object of the present invention is to provide to provide a transparent thin film electroluminescent display element and method for manufacturing the same so as to solve or at least alleviate the prior art disadvantages. The objects of the invention are achieved by a transparent thin film electroluminescent display element which is characterized by what is stated in the independent claim 1. The objects of the invention are achieved by a method for manufacturing a transparent thin film electroluminescent display element which is characterized by what is stated in the independent claim 11.

The preferred embodiments of the invention are disclosed in the dependent claims.

The invention is based on the idea of providing a transparent thin film electroluminescent (TASEL) display element with an emissive area. The display element comprises a layer stack in the emissive area or stacked layer structure. The layer stack comprises a first conductor layer having a first active conductor element, a second conductor layer having a second active conductor element, and an emissive layer superposed between the first and second conductor layers and arranged to emit light in the emissive area upon electrical current flowing through the emissive layer between the first active conductor element and the second active conductor elements. The layer stack further comprises a first dielectric layer provided between the first conductor layer and the emissive layer and a second dielectric layer provided between the second conductor layer and the emissive layer. It should be noted, that that the display element may also comprise other additional material layers, for example surface layers or substrate layers such as glass layer(s). The display element may also comprise optical material layers for adjusting the optical properties of the display element.

The first conductor layer further comprises a first active electrical lead connected to the first active conductor element and arranged to provide electrical connection to the first active conductor element. Accordingly, the first active electrical lead is arranged to extend in the display element and on the first conductor layer and is connected to the first active conductor element.

Similarly, the second conductor layer further comprises a second active electrical lead connected to the second active conductor element and arranged to provide electrical connection to the second active conductor element. Accordingly, the second active electrical lead is arranged to extend in the display element and on the first conductor layer and is connected to the second active conductor element. The first and second active electrical leads are not superposed in the stacked structure of the display element.

Accordingly, electricity may flow via the first active electrical lead to the first active conductor element and through the emissive layer, or the first and second dielectric layers and the emissive layer, to the second active conductor element and further via the second active electrical lead. The emissive layer emits light upon electrical current flowing through the emissive layer between the first active conductor element and the second active conductor element.

According to the present invention the second conductor layer comprises a first passive electrical lead. The first passive electrical lead is separate from the second active conductor element. Thus, the first passive electrical lead is not connected to the second active conductor element in the second conductor layer. Thus, the first passive electrical lead electrically separated from the second active conductor element and from the second active electrical lead in the second conductor layer. Further, electrical current flowing the second active electrical lead and in the second active conductor element does not flow in the first passive electrical lead.

Further, in the present invention one or more first electrical through leads extend between the first active electrical lead and the first passive electrical lead through the first and second dielectric layers and the emissive layer. The one or more first electrical through leads are arranged to provide electrical connection between the first active electrical lead and the first passive electrical lead through the first and second dielectric layers and the emissive layer.

Accordingly, the first active electrical lead in the first conductor layer and the first passive electrical lead in the second conductor layer are electrically connected to each other with one or more, preferably two or more, first electrical through leads extending through the first and second dielectric layers and the emissive layer.

Thus, the first active electrical lead and the first passive electrical lead provide two parallel electrical leads which are connected to each other. This, enables lowering the resistance of the first active electrical lead connected to first active conductor element. Thus, the brightness may be maintained high without providing thick first active electrical lead and compromising the transparency of the display element. Further, providing similar passive first electrical lead in the second conductor layer opposite the first active electrical lead in the first conductor layer provides uniform layout and imperceptible and transparent structure.

As mentioned above in one embodiment, the second conductor layer comprises the second active electrical lead connected to the second active conductor element and arranged to provide electrical connection to the second active conductor element. Further, the first conductor layer comprises a second passive electrical lead. The second passive electrical lead is separate from the first active conductor element. Thus, the second passive electrical lead is not connected to the first active conductor element in the first conductor layer. Thus, the second passive electrical lead electrically separated from the first active conductor element and from the first active electrical lead in the first conductor layer. Further, electrical current flowing the first active electrical lead and in the first active conductor element does not flow in the second passive electrical lead.

Further, one or more second electrical through leads extending between the second active electrical lead and the second passive electrical lead through the first and second dielectric layers and the emissive layer. The one or more second electrical through leads are arranged to provide electrical connection between the second active electrical lead and the second passive electrical lead through the first and second dielectric layers and the emissive layer.

Accordingly, the second active electrical lead in the second conductor layer and the second passive electrical lead in the first conductor layer are electrically connected to each other with one or more, preferably two or more, second electrical through leads extending through the first and second dielectric layers and the emissive layer.

The same benefits are achieved with the second passive electrical lead and the one or more second electrical through leads.

In one embodiment, the display element comprises one or more first through holes extending between the first active electrical lead and the first passive electrical lead through the first and second dielectric layers and the emissive layer. Therefore, one or more electrical connections between the first active electrical lead and the first passive electrical lead are provided.

In another embodiment, the display element comprises one or more first through holes extending between the first active electrical lead and the first passive electrical lead through the first and second dielectric layers and the emissive layer. Further, one or more second through holes extend between the second active electrical lead and the second passive electrical lead through the first and second dielectric layers and the emissive layer. Therefore, one or more electrical connections between the first active electrical lead and the first passive electrical lead are provided, and similarly one or more electrical connections between the second active electrical lead and the second passive electrical lead are provided.

In one embodiment, the one or more first through holes extending through the first and second dielectric layers and the emissive layer are laser cut holes.

In another embodiment, the one or more first through holes and the one or more second through holes extending through the first and second dielectric layers and the emissive layer are laser cut holes.

Laser cut holes are advantageous, as they may be formed with very tiny diameter which does not affect the transparency of the display element. Thus, the electrical connection between the first active electrical lead and the first passive electrical lead and/between the first second electrical lead and the second passive electrical lead may be provided substantially invisible and the transparency of the display element is not compromised.

In one embodiment, the one or more first through holes are provided with electrically conductive material and arranged to provide electrical connection between the first active electrical lead and the first passive electrical lead. Thus, the first through holes are filled or provided with electrically conductive material such that electrical connection is formed between the first active electrical lead and the first passive electrical lead. Further, the electrically conductive material in the first through holes is connected to the first active electrical lead and the first passive electrical lead.

In another embodiment, the one or more first through holes and the one or more second through holes are provided with electrically conductive material and arranged to provide electrical connection between the first active electrical lead and the first passive electrical lead and between the second active electrical lead and the second passive electrical lead, respectively. Thus, the first and second through holes are filled or provided with electrically conductive material such that electrical connection is formed between the first active electrical lead and the first passive electrical lead and between the second active electrical lead and the second passive electrical lead, respectively. Further, the electrically conductive material in the first and second through holes is connected to the first active electrical lead and the first passive electrical lead and to the second active electrical lead and the second passive electrical lead, respectively.

In one embodiment, the one or more first through holes are provided with same material as the first active conductor element or the second active conductor element or the first and the second active conductor elements. Therefore, the first electrical through leads may be provided when the first or second conductor layer is formed by filling the first through holes with the material of the first or second conductor layer.

In another embodiment, the one or more first through holes and the one or more second through holes re provided with same material as the first active conductor element or the second active conductor element or the first and second active conductor elements. Therefore, the first and second electrical through leads may be provided when the first or second conductor layer is formed by filling the first and second through holes with the material of the first or second conductor layer.

In one embodiment, the first active conductor element or the second active conductor element are made of one of the following materials indium tin oxide (ITO). ITO is a preferable material as it is both electrically conductive material and also transparent material. Thus, also the first and second electrical through leads are provided from ITO.

In one embodiment, the first active electrical lead and the first passive electrical lead are arranged opposite to each other in the first conductor layer and in the second conductor layer, respectively. Accordingly, the first active electrical lead and the first passive electrical lead are arranged aligned or extend parallel to each and opposite to each other in the first conductor layer and in the second conductor layer. Thus, they are arranged to follow each other in the first conductor layer and in the second conductor layer.

In another embodiment, the first active electrical lead and the first passive electrical lead are arranged opposite to each other in the first conductor layer and in the second conductor layer, respectively. Further, the second active electrical lead and the second passive electrical lead are arranged opposite to each other in the first conductor layer and in the second conductor layer, respectively. Accordingly, the first active electrical lead and the first passive electrical lead are arranged aligned or extend parallel to each other and opposite to each other in the first conductor layer and in the second conductor layer. Similarly, the second active electrical lead and the second passive electrical lead are arranged aligned or extend parallel to each other and opposite to each other in the first conductor layer and in the second conductor layer. Thus, the second active electrical lead and the second passive electrical lead are arranged to follow each other in the first conductor layer and in the second conductor layer.

In one embodiment, the display element is a segment display element comprising two or more first active conductor elements and two or more first active electrical leads, respectively, in the first conductor layer, and two or more second active conductor elements and two or more second active electrical leads, respectively, in the second conductor layer. In the segment display, the emissive area comprises two or more emissive segments. Each emissive segment is defined by and between opposite first and second active conductor elements. Further, a separate first active electrical lead is provided for and connected to each of the first active conductor elements in the first conductor layer. Similarly, a separate second active electrical lead is provided for and connected to each of the second active conductor elements in the second conductor layer.

Further in the segment display element, the second conductor layer comprises two or more first passive electrical leads arranged opposite to the two or more first active electrical leads in the first conductor layer, respectively. Accordingly, there is a corresponding first passive electrical lead in the second conductor layer for each of the two or more first active electrical leads in the first conductor layer. Thus, each respective and opposite first active electrical lead and first passive electrical lead form a first electrical lead pair.

Additionally, one or more first electrical through leads are arranged to extend between each respective first active electrical lead and first passive electrical lead, or each respective first electrical lead pair of first active electrical lead and first passive electrical lead, through the first and second dielectric layers and the emissive layer.

Alternatively in another embodiment, the second conductor layer comprises two or more first passive electrical leads arranged opposite to the two or more first active electrical leads in the first conductor layer, respectively. Accordingly, there is a corresponding first passive electrical lead in the second conductor layer for each of the two or more first active electrical leads in the first conductor layer. Thus, each respective and opposite first active electrical lead and first passive electrical lead form a first electrical lead pair.

Further, one or more first electrical through leads are arranged to extend between each respective first active electrical lead and first passive electrical lead, or each respective first electrical lead pair of first active electrical lead and first passive electrical lead, through the first and second dielectric layers and the emissive layer.

In this embodiment, the first conductor layer comprises two or more second passive electrical leads arranged opposite to the two or more second active electrical leads in the second conductor layer, respectively. Accordingly, there is a corresponding second passive electrical lead in the first conductor layer for each of the two or more second active electrical leads in the second conductor layer. Thus, each respective and opposite second active electrical lead and second passive electrical lead form a second electrical lead pair.

Further, one or more second electrical through leads are arranged to extend between each respective second active electrical lead and second passive electrical lead, or each respective second electrical lead pair of second active electrical lead and second passive electrical lead, through the first and second dielectric layers and the emissive layer.

Accordingly, the principle of the present invention in which parallel electrical leads are utilized is applied separately to each of the first and second active conductor element or separate emissive segments of the segment display.

In one embodiment of the present invention, the display element is a matrix display element comprising two or more first active conductor traces and two or more first active electrical leads connected to the two or more first active conductor traces, respectively, in the first conductor layer, and two or more second active conductor traces and two or more second active electrical leads connected to the two or more second active conductor traces, respectively, in the second conductor layer.

In a matrix display there is usually two or more first active conductor traces extending adjacent and parallel to each other in a first direction in the first conductor layer. Further, there is two or more second active conductor traces extending adjacent and parallel to each other in a second direction in the second conductor layer. The first and second active conductor traces correspond the first and second conductor elements. The first direction of the first active conductor traces is transverse, preferably, perpendicular to the second direction of the second active conductor traces. Light may be emitted in the intersection areas of the first and second active conductor traces upon electrical current flowing between the intersecting first and second active conductor traces.

In the matrix display element, a separate first active electrical lead is provided for and connected to each of the first active conductor trace in the first conductor layer. Similarly, a separate second active electrical lead is provided for and connected to each of the second active conductor trace in the second conductor layer.

In the matrix display element, the second conductor layer comprises two or more first passive electrical leads arranged opposite to the two or more first active electrical leads in the first conductor layer. Accordingly, there is a corresponding first passive electrical lead in the second conductor layer for each of the two or more first active electrical leads in the first conductor layer. Thus, each respective and opposite first active electrical lead and first passive electrical lead form a first electrical lead pair.

Further, one or more first electrical through leads are arranged to extend between each respective first active electrical lead and first passive electrical lead, or each respective second electrical lead pair of second active electrical lead and second passive electrical lead, through the first and second dielectric layers and the emissive layer.

Accordingly, the principle of the present invention in which parallel electrical leads are utilized is applied separately to each of the first and second active conductor trace of the of the matrix display.

Alternatively in another embodiment of the matrix display, the second conductor layer comprises two or more first passive electrical leads arranged opposite to the two or more first active electrical leads in the first conductor layer, respectively. Accordingly, there is a corresponding first passive electrical lead in the second conductor layer for each of the two or more first active electrical leads in the first conductor layer. Thus, each respective and opposite first active electrical lead and first passive electrical lead form a first electrical lead pair.

Further, one or more first electrical through leads are arranged to extend between each respective first active electrical lead and first passive electrical lead, or each respective first electrical lead pair of first active electrical lead and first passive electrical lead, through the first and second dielectric layers and the emissive layer.

In this embodiment, the first conductor layer comprises two or more second passive electrical leads arranged opposite to the two or more second active electrical leads in the second conductor layer, respectively. Accordingly, there is a corresponding second passive electrical lead in the first conductor layer for each of the two or more second active electrical leads in the second conductor layer. Thus, each respective and opposite second active electrical lead and second passive electrical lead form a second electrical lead pair.

Further, one or more second electrical through leads are arranged to extend between each respective second active electrical lead and second passive electrical lead, or each respective second electrical lead pair of second active electrical lead and second passive electrical lead, through the first and second dielectric layers and the emissive layer.

Accordingly, the principle of the present invention in which parallel electrical leads are utilized is applied separately to each of the first and second active conductor traces of the matrix display.

The present invention further relates to a method for manufacturing a transparent thin film electroluminescent (TASEL) display element having an emissive area. The method comprises steps:
a) providing a first conductor layer, the first conductor layer comprising a first active conductor element and a first active electrical lead connected to the first active conductor element for providing electrical connection to the first active conductor element;
b) providing a first dielectric layer on the first conductor layer;
c) providing an emissive layer on the first dielectric layer;
d) providing a second dielectric layers on the emissive layer; and
e) providing a second conductor layer on the second dielectric layer, the second conductor layer comprising a second active conductor element and a second active electrical lead connected to the second active conductor element for providing electrical connection to the second active conductor element

The emissive layer emits light in the emissive area upon electrical current flowing through the emissive layer between the first active conductor element and the second active conductor element.

The above mentioned stacked structure of the display element is usually formed by utilizing one or more material deposition methods. One or more different deposition methods may be used to form the different layers of the display element.

The stacked structure is usually formed on a substrate, such as glass or plastic. The stacked structure and the display element is provided or formed by first providing or depositing the first conductor layer on the substrate. The first conductor layer has predetermined pattern(s). Then, the first dielectric layer, the emissive layer and the second dielectric layer are successively provided, formed or deposited on the first conductor layer. After that, the second conductor layer is formed or provided or deposited the first dielectric layer. The first conductor layer has also a predetermined pattern(s).

The predetermined pattern(s) of the first conductor layer form the one or more first active conductor elements and the first active electrical leads. The predetermined pattern(s) of the second conductor layer form the one or more second active conductor elements and the second active electrical leads.

According to the present invention, the step e) further comprises providing to the second conductor layer a first passive electrical lead. The first passive electrical lead is separate from the second active conductor element. Thus, predetermined pattern(s) of the second conductor layer comprises or forms also the first passive electrical lead.

Further, the method further comprises step f) providing electrical connection between the first active electrical lead and the first passive electrical lead through the first and second dielectric layers and the emissive layer. Thus, the first active electrical lead in the first conductor layer and the first passive electrical lead in the second conductor layer are connected to each other through the first and second dielectric layers and the emissive layer.

The method of the present invention is characterized in that it provides the above described transparent thin film electroluminescent display element.

In one embodiment of the method, the step a) further comprises providing to the first conductor layer a second passive electrical lead. The second passive electrical lead is separate from the first active conductor element. Thus, predetermined pattern(s) of the first conductor layer comprises or forms also the second passive electrical lead.

The method further comprises step g) providing electrical connection between the second active electrical lead and the second passive electrical lead through the first and second dielectric layers and the emissive layer. Thus, the second active electrical lead in the second conductor layer and the second passive electrical lead in the first conductor layer are connected to each other through the first and second dielectric layers and the emissive layer.

In one embodiment of the invention, the step f) comprises forming one or more first through holes through the first and second dielectric layers and the emissive layer and providing electrically conductive material to the one or more first through holes for providing electrical connection between the first active electrical lead and the first passive electrical lead.

The through holes and the electrically conductive material provide electric connection between the first active electrical lead and the first passive electrical lead.

In another embodiment, the step f) comprises forming one or more first through holes through first and second dielectric layers and the emissive layer and providing electrically conductive material to the one or more first through holes for providing electrical connection between the first active electrical lead and the first passive electrical lead. In this embodiment, the step g) further comprises forming one or more second through holes through first and second dielectric layers and the emissive layer and providing electrically conductive material to the one or more second through holes for providing electrical connection between the second active electrical lead and the second passive electrical lead.

The through holes and the electrically conductive material provide electric connection between the first active electrical lead and the first passive electrical lead and between the second active electrical lead and the second passive electrical lead, respectively.

In one embodiment, the first through holes or the first and second through holes are preferably formed to a stacked layer comprising the first conductor layer, the first dielectric layer, the emissive layer and the second dielectric layer. Thus, the through holes through first and second dielectric layers and the emissive layer are formed before forming the second conductor layer.

Accordingly, in one embodiment the method comprises forming the first conductor layer, the first dielectric layer, the emissive layer and the second dielectric layer and then forming the through holes through first and second dielectric layers and the emissive layer. After that, the second conductor layer is formed and step e) carried out.

In one embodiment of the method, the step f) comprises forming the one or more first through holes by laser cutting.

In another embodiment, the step f) comprises forming the one or more first through holes by using laser pulses.

In a further embodiment, the steps f) and g) comprise forming the one or more first through holes and the one or more second through holes by laser cutting.

In a yet further embodiment, the steps f) and g) comprise forming the one or more first through holes and the one or more second through holes by using laser pulses.

In one embodiment, the method comprises carrying out first the steps a), b), c) and d), and then carrying out step f) by forming the one or more first through holes in connection with the first active electrical lead. The method further comprises carrying out the step e) after the step d). The step e) comprises utilizing a material deposition method for providing the second conductor layer from an electrically conductive deposition material and the step f) comprises filling the one or more first through holes with the electrically conductive deposition material during step e) upon providing the first passive electrical lead.

Thus, the electrical connection between the first active electrical lead and the first passive electrical lead is carried out simultaneously with providing the second conductor layer.

In another embodiment, the method comprises carrying out first the steps a), b), c) and d), and then carrying out step f) by forming the one or more first through holes in connection with the first active electrical lead and step g) by forming the one or more second through holes in connection with the second passive electrical lead. The method further comprises carrying out the step e) after the steps f) and g), the step e) comprises utilizing a material deposition method for providing the second conductor layer from an electrically conductive deposition material. The step f) comprises filling the one or more first through holes with the electrically conductive deposition material during step e) upon providing the first passive electrical lead, and the step g) comprises filling the one or more second through holes with the electrically conductive deposition material during step e) upon providing the second active electrical lead.

Thus, the electrical connection between the first active electrical lead and the first passive electrical lead and between the second active electrical lead and the second passive electrical lead, respectively, is carried out simultaneously with providing the first conductor layer.

In one embodiment, steps a) and e) comprise providing the first and second conductor layers from indium tin oxide (ITO).

In another embodiment, steps a) and e) comprise providing the first and second conductor layers from indium tin oxide (ITO) by sputtering.

An advantage of the invention is that the active electrical leads may be provided as two parallel electrical leads such that the resistance of the electrical lead in the display element is decreased. Thus, use of thick electrical leads affecting negatively to transparency of the display element may be avoided. Further, the use of parallel electrical leads provides substantially uniform patterns in the first and second conductor layers provides balancing optical and transparency properties to the both sides of the display element. Additionally, the parallel coupling of the active and passive electric leads on opposite conductor layers may be efficiently manufactured during the normal manufacturing process of the display element.

### BRIEF DESCRIPTION OF THE DRAWINGS

The invention is described in detail by means of specific embodiments with reference to the enclosed drawings, in which

FIGS. 1 and 2 show schematically stacked structures of transparent thin film electroluminescent display elements;

FIGS. 3 and 4 show schematically first and second conductor layers of a display element;

FIG. 5 shows schematically the structure of display element;

FIGS. 6 and 7 schematically first and second conductor layers of a display element according to the present invention;

FIG. 8 shows schematically a structure of display element according to the present invention; and

FIGS. 9 and 10 show schematically a stacked layer structure a display element according to the present invention;

FIG. 11 shows a cross sectional view of a stacked layer structure a display element according to the present invention;

FIGS. 12, 13, 14, 15, 16 and 17 show schematically a stacked layer structure of a matrix display element according to the present invention.

### DETAILED DESCRIPTION OF THE INVENTION

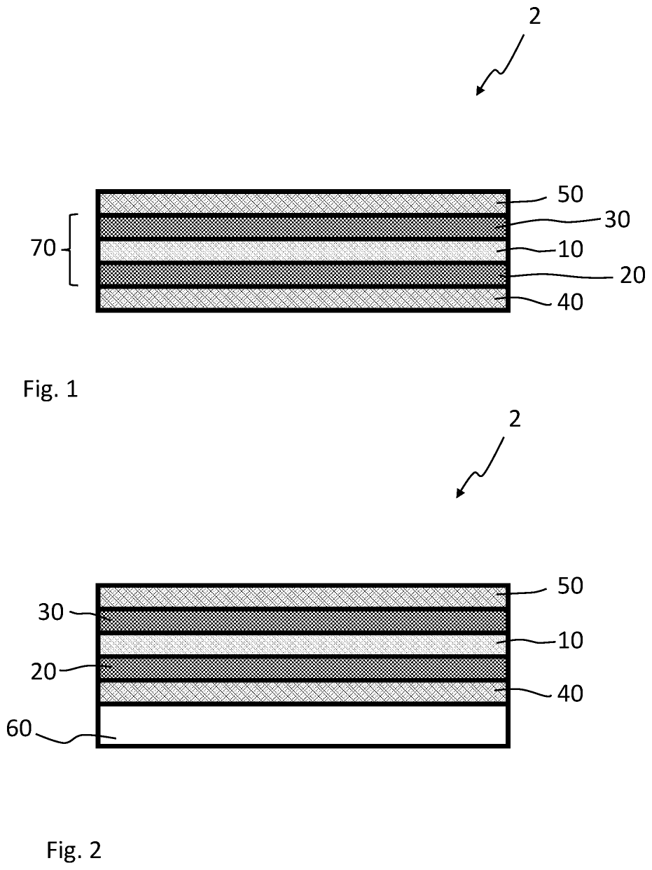

FIG. 1 shows schematically stacked layer structure of a transparent thin film electroluminescent display element 2. The layers are stacked in thickness direction of the display element 2 and the layers extend in lateral direction of the display element 2.

The stacked layer structure comprises a first conductor layer 40 and a second conductor layer 50. Further, there is an emissive layer 10 superposed between the first and second conductor layers 40, 50. Between the first and second conductor layers there is also a first dielectric layer 20 and second dielectric layer 30. The first dielectric layer 20 is provided between the first conductor layer 40 and the emissive layer 10 and the second dielectric layer 30 provided between the second conductor layer 50 and the emissive layer 10.

The first dielectric layer 20, the emissive layer 10 and the second dielectric layer 30 form together a so called DSD-layer 70 provided between the first conductor layer 40 and the second conductor layer 50.

The emissive layer 10 is arranged to emit light upon electrical current flowing through the emissive layer 10 between the first and the second conductor layers 40, 50.

The first and second conductor layers 40, 50 have patterned structures such that the first conductor layer 40 comprises one or more first active conductor elements and the second conductor layer 50 comprises one or more second active conductor elements. The emissive layer 10 is arranged to emit light in the areas (only in the areas) of the display element in which the first active conductor elements of the first conductor layer 40 and the second active conductor elements of the second conductor layer 50 are superposed, upon electrical current flowing through the emissive layer 10 between the first active conductor elements and the second active conductor elements. Areas where the first active conductor elements and the second active conductor elements are superposed in the stacked structure form emissive areas of the display element. Therefore, the display element 2 comprises at least one emissive area.

During operation, an electric field is provided in the emissive layer by supplying a voltage difference between the first conductor layer or first active conductor element and second conductor layer or second conductor element such the electrons are discharged into the emissive layer, giving rise to light emission. Generally, operation of the display element is based on a luminescent material of the emissive layer that emits light when exposed to an external electric field.

FIG. 2 shows an embodiment in which display element 2 comprises the stacked structure 10, 20, 30, 40, 50 of FIG. 1 provided on a substrate layer or surface layer 60. The substrate layer 60 is usually a transparent layer.

In the present application “conductor” refers to electrical conductor and electrical conductivity thereof. “Conductive” correspondingly refers to electrically conductive materials or structures.

“Transparent” refers to optical transparency of the display element and the layers, parts and materials thereof in the relevant wavelength range at issue. In other words, “transparent” material or structure refers to a material or structure allowing light, or generally electromagnetic radiation, at such relevant wavelength range to propagate through such material or structure. The relevant wavelength range may depend on the application where the transparent display element is to be used. In some embodiments, the relevant wavelength range may be the visible wavelength range of about 390 to about 700 nm.

The emissive layer 10 may comprise, for example, manganese doped zinc sulfide ZnS:Mn as the luminescent material. Also other luminescent materials are possible.

The first and the second dielectric layers 20, 30 may comprise, for example, antimony tin oxide (ATO) or any other appropriate dielectric material.

The first and the second conductor layers 40, 50, and the active conductor elements thereof, may comprise, for example, indium tin oxide (ITO), aluminum doped zinc oxide ATO (ZnO:Al), or any other appropriate transparent conductive oxide (TCO) or other transparent conductor material. Preferably, ITO is used for the first and second conductor layer 40, 50.

The transparent substrate 60 is formed of glass, such as sodalime or aluminosilicate glass, or some other suitable material such as any other appropriate transparent glass or plastic. Possible plastic materials also comprise, for example, polyethylene PE, and polycarbonate PC, without being limited to these examples.

The transparent display element 2, including the substrate thereof, may be formed as a rigid structure or a flexible and/or bendable structure enabling attaching or laminating thereof on a curved, or any freely shaped three dimensional surface.

In other embodiments, any of the emissive layer, the first and the second dielectric layers, and the first and the second conductor layers may comprise a plurality of sublayers of different materials or compositions. Further, the display element 2 may also comprise one or more additional material layers, for example between the first conductor layer 40 and the substrate layer 60. Accordingly, the present invention is not limited embodiments having only exactly the material layers of FIGS. 1 and 2.

The stacked structure of the display element 2 is formed by utilizing deposition method(s) for forming material layers. Same or different deposition methods may be used for different material layers 10, 20, 30, 40, 50. The applicable deposition methods comprise, but are not limited to, atomic layer deposition (ALD), chemical vapour deposition (CVD) or the like gas phase deposition methods, or sputtering or the like deposition methods.

Forming the stacked structure of the display element 2 of the transparent electroluminescent display with at least one emissive area comprises at least the following steps.

The method comprises forming, on a transparent substrate 60, the stacked structure of the display element. Forming said stacked structure comprises in a first step forming, the first conductor layer 40 on the substrate 60. Any appropriate deposition method, such as sputtering or atomic layer deposition ALD, may be used in said forming.

Sputtering is preferred deposition method for forming the first conductive layer 40.

In a second step, the first dielectric layer 20 is formed on the first conductor layer 40. The second step and forming of the first dielectric layer 20 may be carried out by any appropriate deposition method such a ALD or sputtering.

Then in a third step, the emissive layer 10 is formed on the first dielectric layer 20. Again, any appropriate deposition method, such as sputtering or ALD, may be utilized.

Further, in a fourth step, the second dielectric layer 30 is formed on the emissive layer 10. The fourth step and forming of the second dielectric layer 30 may be carried out by any appropriate deposition method such a ALD or sputtering.

ALD is preferred deposition method for forming the first and second dielectric layers 20, 30 and the emissive layer 10.

Then in a fifth step, the second conductor layer 50 is formed on the second dielectric layer 30. Any appropriate deposition method, such as sputtering or atomic layer deposition ALD, may be used in said forming.

Sputtering may be preferred deposition method for forming the second conductive layer 50.

Further, in some embodiment the method further comprises a sixth step in which a cover layer (not shown) is provided on the second conductor layer 50.

Forming a layer “on” another layer or some other existing structure does not necessitate forming it directly on, i.e. so as to have a direct contact with, that other layer or structure, but there may be any appropriate intermediate layer (s) and structure (s) therebetween. Thus, the method may comprise in some embodiment also forming additional layers between the mentioned layers 10, 20, 30, 40, 50, 60.

The first and the second conductor layers 40, 50 are patterned layers so as to have active conductor elements. The active conductor elements may be separate segment elements in a segment display or elongated conductor traces in a matrix display. The patterned structure of the first and second conductor layers 40, 50 may be provided during forming the first and second conductor layers 40, 50 for example by utilizing photolithography or other known surface patterning technologies known in the art like laser patterning or mechanical patterning. For example in photolithography, light (UV light or visible light) is used to transfer a geometric pattern from a photomask to a photosensitive or light-sensitive chemical photoresist on the substrate or already deposited thin films on the substrate. A series of chemical treatments then either etches the exposure pattern into the material or enables deposition of a new material in the desired pattern upon the material underneath the photoresist. In laser patterning, a beam of laser is used to ablate material from the substrate or thin film structure, applicable also selectively to thin material layers. In mechanical patterning, a precision grinder or other precision mechanical instrument is used to remove material selectively from a thin film structure or from a substrate.

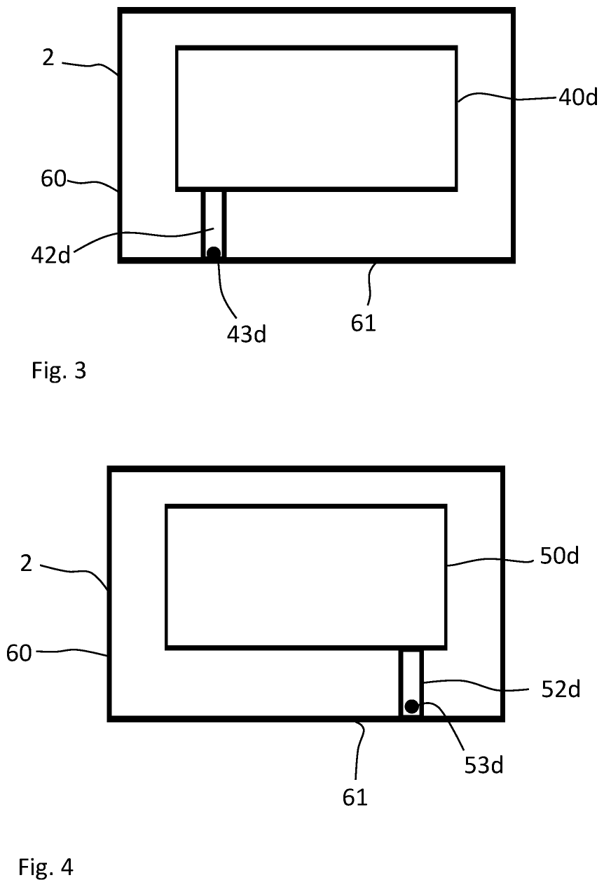

FIGS. 3 and 4 show a display element 2 according to FIG. 2 and according to conventional prior art. FIGS. 3 and 4 show, a simplified display element 2 with only one first active conductor element 40d in the first conductor layer 40 and only one second active conductor element 50d in the second conductor layer 50 in segment display. However, there may be also two or more first active conductor elements 40d in the first conductor layer 40 and two or more second active conductor elements 50d in the second conductor layer 50 in segment display.

As shown in FIG. 3, the first conductor layer 40 comprises the first active conductor element 40d formed on the substrate layer 60. The first conductor layer 40 further comprises a first active electrical lead 42d connected to the first active conductor element 40d and arranged to provide electrical connection to the first active conductor element 40d. Accordingly, electrical current may flow along the first active electrical lead 42d to/from the first active conductor element 40d.

The first electrical lead 42d is made of electrically conductive material. The first active electrical lead 42d is preferably formed from the same material and in the same method step, in the first method step, as the first conductor layer 40 and the first active conductor element 40d. Thus, the first electrical lead 42d may be formed from ITO.

Accordingly, the first conductor layer 40 comprises the first active conductor element 40d and the first active electrical lead 42d.

The first electrical lead 42d extends from a first side edge 61, or from the vicinity thereof, of the substrate layer 60 to the first active conductor element 40d. The first active electrical lead 42d is provided or connected to an electrical connector or a first electrical pad 43d via which the electrical current is provided to/from the first active electrical lead 42d.

FIG. 4 shows the second conductor layer 50. FIG. 4 shows the opposite side of the display element 2 of FIG. 3. As shown in FIG. 4, the second conductor layer 50 comprises the second active conductor element 50d on the second dielectric layer 30. The second conductor layer 50 further comprises a second active electrical lead 52d connected to the second active conductor element 50d and arranged to provide electrical connection to the second active conductor element 50d. Accordingly, electrical current may flow along the second active electrical lead 52d to/from the second active conductor element 50d.

The second electrical lead 52d is made of electrically conductive material. The second active electrical lead 52d is preferably formed from the same material and in the same method step, in the fifth method step, as the second conductor layer 40 and the second active conductor element 50d. Thus, the second electrical lead 52d may be formed from ITO.

Accordingly, the second conductor layer 50 comprises the second active conductor element 50d and the second active electrical lead 52d.

The second electrical lead 52d extends from the first side edge 61, or from the vicinity thereof, of the substrate layer 60 to the second active conductor element 50d. The second active electrical lead 52d is provided or connected to a second electrical connector or an electrical pad 53d via which the electrical current is provided to/from the second active electrical lead 52d.

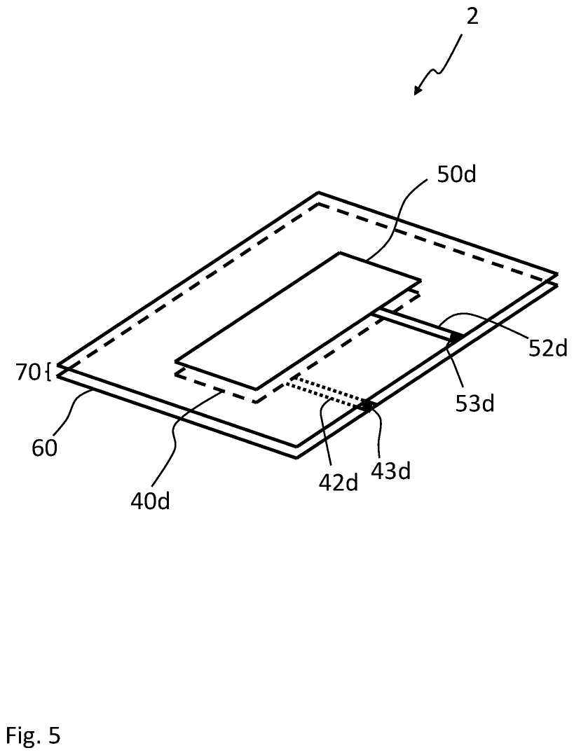

FIG. 5 shows schematically an axonometric view of the display element 2, and the layered structure thereof, of FIGS. 2, 3 and 4. As shown in FIG. 5, first active conductor element 40d of the first conductor layer 40 and the second active conductor element 50d of the second conductor layer 50 are arranged superposed relative to each other or directly opposite to each other on opposite sides of the DSD-layer 70. Thus, electrical current may flow between the first and second active conductor elements 40d, 50d through the DSD-layer 70 such that the emissive layer 10 in the DSD-layer can emit light.

However, the first active electrical lead 42d and the second active electrical lead 52d are not superposed relative to each other or opposite to each other. Thus, the first active electrical lead 42d and the second active electrical lead 52d are arranged displaced relative to each other. Therefore, electrical current does not flow through DSD-layer 70 in the location of the first active electrical lead 42d and the second active electrical lead 52d. Further, the emissive layer 10 does not emit light in the location of the first active electrical lead 42d and the second active electrical lead 52d. The first active electrical lead 42d and the second active electrical lead 52d only conduct electrical current to/from the first and second conductor elements 40d, 50d, respectively.

In FIG. 5, the first and second conductor layer 40, 50 and the DSD-layer 70 are on the substrate 60.

Further it should be noted, that the display element 2 may comprise also one or more first active conductor elements 40d and one or more first active electrical leads 42d in the first conductor layer 40 and one or more second active conductor elements 50d and one or more second active electrical leads 52d in the second conductor layer 50 arranged as described above and shown in FIG. 5.

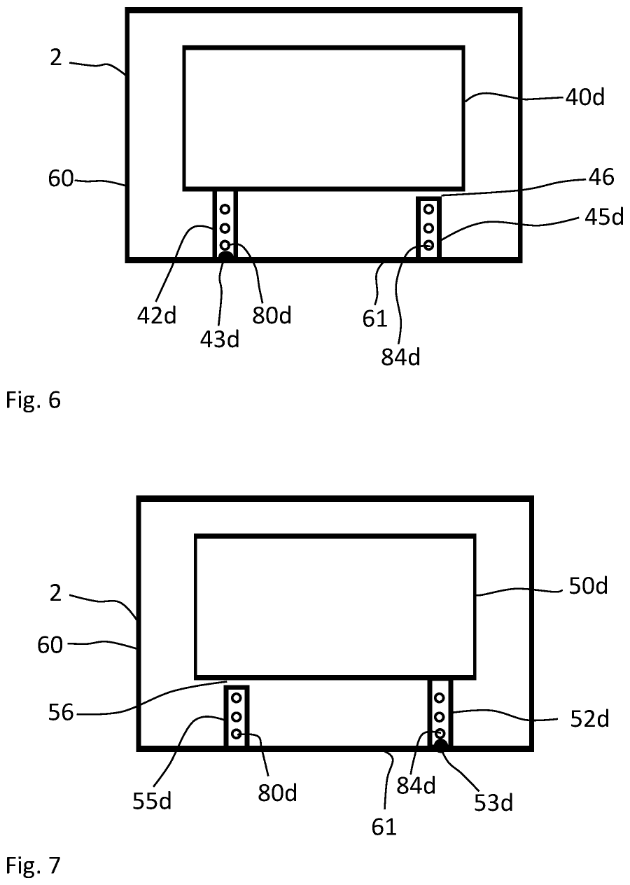

FIG. 6 shows a display element 2 according to the present invention. FIG. 6 shows the first conductor layer 40. The first conductor element 40d and the first electrical lead 42d correspond the display element of FIG. 3.

Further, the display element 2 of FIG. 6 substantially corresponds the display element 2 of FIG. 3.

In the display element of FIG. 6, the first conductor layer 40 further comprises a second passive electrical lead 45d. The second passive electrical lead 45d is separate passive electrical lead. Thus, the second passive electrical lead 45d is separate from the first conductor element 40d and from the first active electrical lead 42d. Accordingly, the second passive electrical lead 45d is disconnected from the first conductor element 40d and from the first active electrical lead 42d. Further, the second passive electrical lead 45d is not connected to electricity or power supply.

In the context of this application term passive electrical lead means that the electrical lead is disconnect or separate from active electrical leads and conductor elements and also from other passive electrical leads in the same conductor layer.

Further, the display element 2 of FIG. 6 is provided with one or more first electrical through leads 80d extending between the first conductor layer 40 and the second conductor layer 50 through the DSD-layer 70. There may be one or more separate first electrical through leads 80d. The first electrical through leads 80d are made of electrically conductive material and arranged to provide electrical connection between the first and second conductor layers 40, 50.

The one or more first electrical through leads 80d are arranged in connection with the first active electrical lead 42d and arranged to provide electrical connection between the first active electrical lead 42d and the second conductor layer 50. Thus, the one or more first electrical through leads 80d are provided to the first active electrical lead 42d and arranged to extend from the first active electrical lead 42d to the second conductor layer 50 through DSD-layer 70.

The display element 2 of FIG. 6 is also provided with one or more second electrical through leads 84d extending between the first conductor layer 40 and the second conductor layer 50 through the DSD-layer 70. There may be one or more separate second electrical through leads 84d. The second electrical through leads 84d are made of electrically conductive material and arranged to provide electrical connection between the first and second conductor layers 40, 50.

The one or more second electrical through leads 84d are arranged in connection with the second passive electrical lead 45d and arranged to provide electrical connection between the second passive electrical lead 45d and the second conductor layer 50. Thus, the one or more second electrical through leads 84d are provided to the second passive electrical lead 45d and arranged to extend from the second passive electrical lead 45d to the second conductor layer 50 through DSD-layer 70.

FIG. 7 shows a display element 2 according to the present invention. FIG. 7 shows the opposite side of the display element 2 of FIG. 6. FIG. 7 shows the second conductor layer 50. The second conductor element 50d and the second electrical lead 52d correspond the display element of FIG. 4.

Further, the display element 2 of FIG. 7 substantially corresponds the display element 2 of FIG. 4.

In the display element of FIG. 7, the second conductor layer 50 further comprises a first passive electrical lead 55d. The first passive electrical lead 55d is a separate passive electrical lead. Thus, the first passive electrical lead 55d is separate from the second conductor element 50d and from the second active electrical lead 52d. Accordingly, the first passive electrical lead 55d is disconnected from the second conductor element 50d and from the second active electrical lead 52d. Further, the first passive electrical lead 55d is not connected to electricity or power supply.

Further, the display element 2 of FIG. 7, as also shown in FIG. 6, is provided with the one or more first electrical through leads 80d extending between the first conductor layer 40 and the second conductor layer 50 through the DSD-layer 70. The one or more first electrical through leads 80d are arranged in connection with the first passive electrical lead 55d and arranged to provide electrical connection between the first passive electrical lead 55d and the first conductor layer 40. Thus, the one or more first electrical through leads 80d are provided to the first passive electrical lead 55d and arranged to extend from the first passive electrical lead 55d to the first conductor layer 40 through DSD-layer 70.

The display element 2 of FIG. 7, as also shown in FIG. 6, is also provided with the one or more second electrical through leads 84d extending between the first conductor layer 40 and the second conductor layer 50 through the DSD-layer 70. The one or more second electrical through leads 84d are arranged in connection with the second active electrical lead 52d and arranged to provide electrical connection between the second active electrical lead 52d and the first conductor layer 40. Thus, the one or more second electrical through leads 84d are provided to the second active electrical lead 52d and arranged to extend from the second active electrical lead 52d to the first conductor layer 40 through DSD-layer 70.

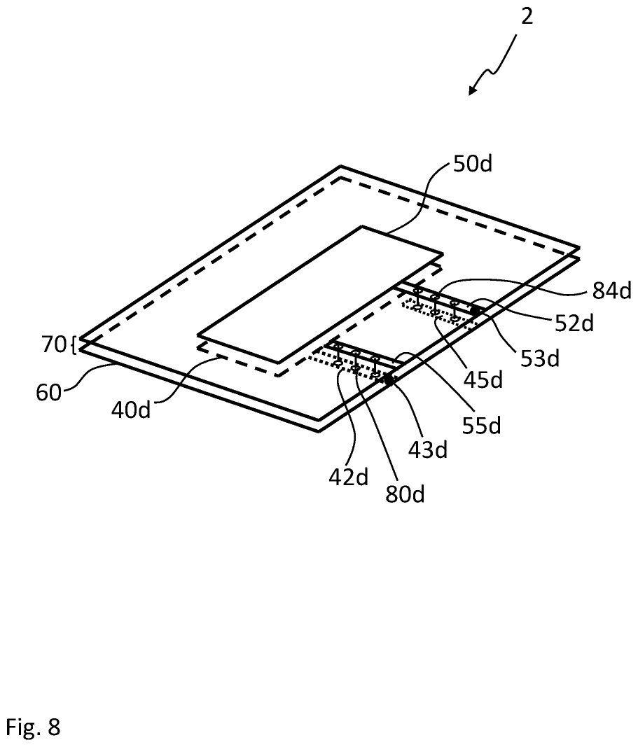

FIG. 8 shows schematically an axonometric view of the display element 2, and the layered structure thereof, of FIGS. 6 and 7. The display element 2 of FIG. 8 also substantially corresponds the display element 2 of FIG. 5. As shown in FIG. 8, the first active conductor element 40d of the first conductor layer 40 and the second active conductor element 50d of the second conductor layer 50 are arranged superposed relative to each other or opposite to each other. Thus, electrical current may flow between the first and second active conductor elements 40d, 50d through the DSD-layer 70 such that the emissive layer 10 in the DSD-layer can emit light.

Further, the first active electrical lead 42d and the second active electrical lead 52d are not superposed relative to each other or opposite to each other. Thus, the first active electrical lead 42d and the second active electrical lead 52d arranged displaced relative to each other. Therefore, electrical current does not flow through DSD-layer 70 in the location of the first active electrical lead 42d and the second active electrical lead 52d. Further, the emissive layer 10 does not emit light in the location of the first active electrical lead 42d and the second active electrical lead 52d. The first active electrical lead 42d and the second active electrical lead 52d only conduct electrical current to/from the first and second conductor elements 40d, 50d, respectively.

However, the first active electrical lead 42d in the first conductor layer 40 and the first passive electrical lead 55d in the second conductor layer 50 are superposed relative to each other or directly opposite to each other on opposite sides of the DSD-layer 70. Further, the one or more first electrical through leads 80d are arranged to extending between the first conductor layer 40 and the second conductor layer 50 through the DSD-layer 70 and further between the first active electrical lead 42d and the first passive electrical lead 55d. Thus, the one or more first electrical through leads 80d are arranged to provide electrical connection between the first active electrical lead 42d and the first passive electrical lead 55d through the DSD-layer 70. Accordingly, the one or more first electrical through leads 80d are arranged in connection with the first passive electrical lead 55d and the first active electrical lead 42d.

Therefore, the one or more first electrical through leads 80d are connected to the first passive electrical lead 55d and the first active electrical lead 42d.

Preferably, the display element 2 comprises two or more separate first electrical through leads 80d provided along the length of the first active electrical lead 42d towards the first conductor element 40d.

Thus, there may be also two or more separate first electrical through leads 80d provided along the length of the first passive electrical lead 55d towards the first conductor element 40d.

Accordingly, electric current flowing to/from the first conductor element 40d flows in along both the first passive electrical lead 55d and the first active electrical lead 42d. Thus, resistance is decreased.

Further, the second active electrical lead 52d in the second conductor layer 50 and the second passive electrical lead 45d in the first conductor layer 40 are superposed relative to each other or directly opposite to each other on opposite sides of the DSD-layer 70. Further, the one or more second electrical through leads 84d are arranged to extend between the first conductor layer 40 and the second conductor layer 50 through the DSD-layer 70 and further between the second active electrical lead 52d and the second passive electrical lead 45d. Thus, the one or more second electrical through leads 84d are arranged to provide electrical connection between the second active electrical lead 52d and the second passive electrical lead 45d through the DSD-layer 70. Accordingly, the one or more second electrical through leads 84d are arranged in connection with the second passive electrical lead 45d and the second active electrical lead 52d.

Therefore, the one or more second electrical through leads 84d are connected to the second passive electrical lead 45d and the second active electrical lead 52d.

Preferably, the display element 2 comprises two or more separate second electrical through leads 84d provided along the length of the second active electrical lead 52d towards the second conductor element 50d.

Thus, there may be also two or more separate second electrical through leads 84d provided along the length of the second passive electrical lead 45d towards the second conductor element 50d.

Accordingly, electric current flowing to/from the second conductor element 50d flows in along both the second passive electrical lead 45d and the second active electrical lead 52d. Thus, resistance is decreased.

In FIG. 8, the first and second conductor layer 40, 50 and the DSD-layer 70 are provided on the substrate 60.

Further it should be noted, that the display element 2 may comprise also one or more first active conductor elements 40d and one or more first active electrical leads 42d and one or more second passive electrical leads 45d in the first conductor layer 40 and one or more second active conductor elements 50d and one or more second active electrical leads 52d and one or more first passive electrical leads 55d in the second conductor layer 50 arranged as described above and shown in FIG. 8.

Further, it should be noted that the first or second passive electrical lead(s) 45d, 55d and the first or second electrical through leads 80d, 84d, respectively, may be omitted.

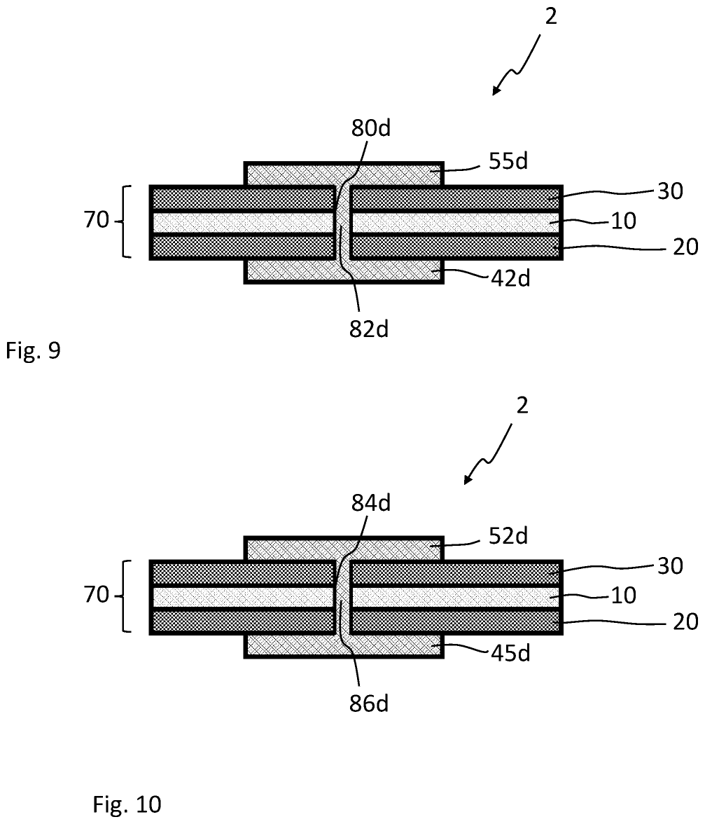

FIG. 9 shows schematically cross-sectional view of the electrical connection between the first active electrical lead 42d and the first passive electrical lead 55d through the DSD-layer 70. As shown in FIG. 9, the first electrical through lead 80d extends from the first active electrical lead 42d to the first passive electrical lead 55d through the DSD-layer 70. Further, the first electrical through lead 80d is connected to the first active electrical lead 42d and to the first passive electrical lead 55d through the DSD-layer 70.

Accordingly, the first electrical through lead 80d enables providing the first active electrical lead 42d and the first passive electrical lead 55d as one first electrical lead connected to the first conductor elements 40d. The connection to the first conductor element 40d is provided with the first active electrical lead 42d.

The first electrical through lead 80d comprises one or more first through holes 82d extending between the first active electrical lead 42d and the first passive electrical lead 55d through the first and second dielectric layers 20, 30 and the emissive layer 10, meaning the DSD-layer 70.

The one or more first through holes 82d are provided with electrically conductive material and arranged to provide electrical connection between the first active electrical lead 42d and the first passive electrical lead 55d.

In some embodiments, the one or more first through holes 82d are provided with same material as the first active conductor element 40d or the second active conductor element 50d, or the first and the second active conductor elements 40d, 50d. Thus, the first through holes 82d may be provided with the electrically conductive material in the same manufacturing step or deposition step as the first and/or the second active conductor elements 40d, 50d.

In some embodiments, the one or more first through holes 82d are provided with same material as the first active electrical lead 42d, or the first passive electrical lead 55d or the first active electrical lead 42d and the first passive electrical lead 55d. Thus, the first through holes 82d may be provided with the electrically conductive material in the same manufacturing step or deposition step as the first active electrical lead 42d and/or the first passive electrical lead 55d.

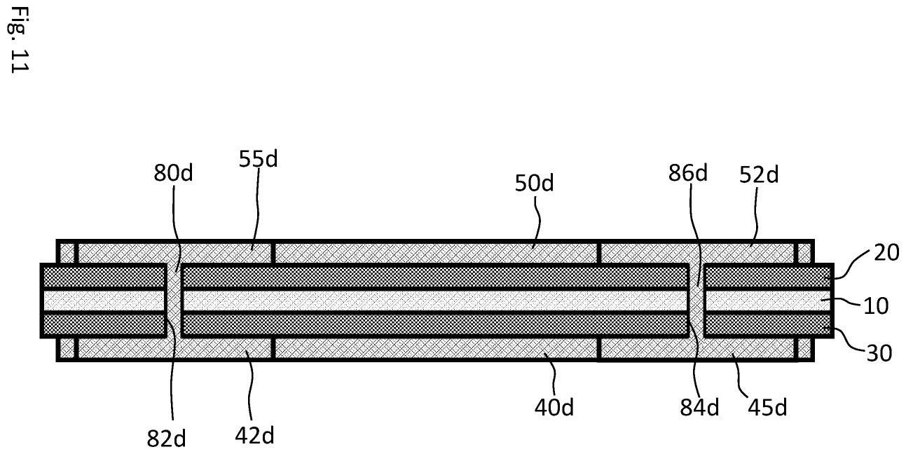

FIG. 10 shows schematically a cross-sectional view of the electrical connection between the second active electrical lead 52d and the second passive electrical lead 45d through the DSD-layer 70. As shown in FIG. 10, the second electrical through lead 84d extends from the second active electrical lead 52d to the second passive electrical lead 45d through the DSD-layer 70. Further, the second electrical through lead 84d is connected to the second active electrical lead 52d and to the second passive electrical lead 45d through the DSD-layer 70.

Accordingly, the second electrical through lead 84d enables providing the second active electrical lead 52d and the second passive electrical lead 45d as one second electrical lead connected to the second conductor elements 50d. The connection to the second conductor element 50d is provided with the second active electrical lead 52d.

The second electrical through lead 84d comprises one or more second through holes 86d extending between the second active electrical lead 52d and the second passive electrical lead 45d through the first and second dielectric layers 20, 30 and the emissive layer 10, meaning the DSD-layer 70.

The one or more second through holes 86d are provided with electrically conductive material and arranged to provide electrical connection between the second active electrical lead 52d and the second passive electrical lead 45d.

In some embodiments, the one or more second through holes 84d are provided with same material as the first active conductor element 40d or the second active conductor element 50d, or the first and the second active conductor elements 40d, 50d. Thus, the second through holes 86d may be provided with the electrically conductive material in the same manufacturing step or deposition step as the first and/or the second active conductor elements 40d, 50d.

In some embodiments, the one or more second through holes 86d are provided with same material as the first active electrical lead 42d, or the first passive electrical lead 55d or the first active electrical lead 42d and the first passive electrical lead 55d. Thus, the second through holes 86d may be provided with the electrically conductive material in the same manufacturing step or deposition step as the first active electrical lead 42d and/or the first passive electrical lead 55d.

In preferable embodiments, the one or more first through holes 82d and the one or more second through holes 86d extending through the first and second dielectric layers 20, 30 and the emissive layer 10 are laser cut holes.

Further in some embodiments, the first active conductor element 40d or the second active conductor element 50d, or the first and the second active conductor elements 40d, 50d are made of ITO. Thus, also the one or more second through holes 86d are provided with ITO as the electrically conductive material.

Further in some embodiments, the first active electrical lead 42d, or the first passive electrical lead 55d or the first active electrical lead 42d and the first passive electrical lead 55d are made of ITO. Thus, also the one or more second through holes 86d are provided with ITO as the electrically conductive material.

FIG. 11 shows the cross-sectional view of the display element 2 of FIG. 8. FIG. 11 thus shows the electrical connections between the first active electrical lead 42d and the first passive electrical lead 55d, and between the second active electrical lead 52d and the second passive electrical lead 45d. Thus, FIG. 11 shows the FIGS. 9 and 10 in combination.

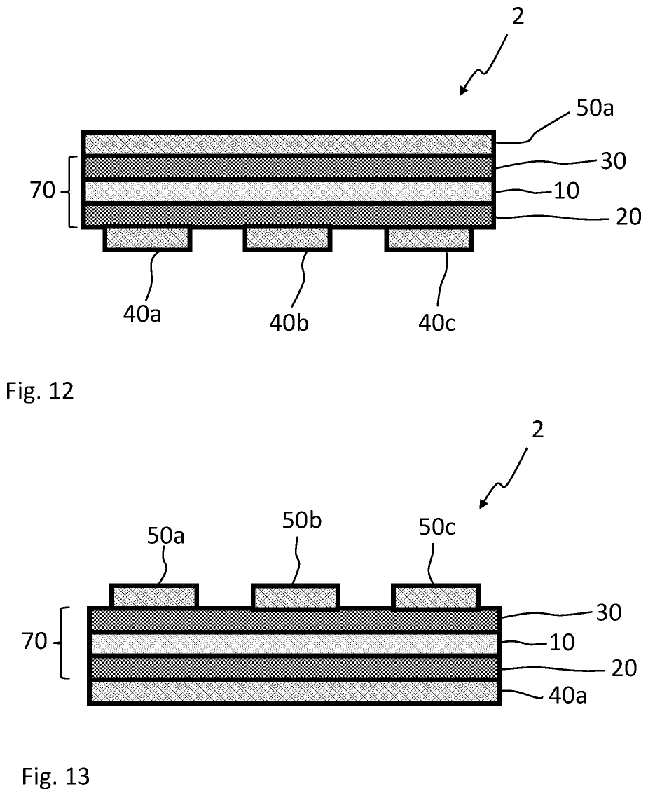

FIGS. 12 to 17 show the present invention in connection with a matrix display element 2.

As shown in FIGS. 12 and 13, in the matrix display the first and the second conductor layers 40, 50 are patterned so as to have elongated conductor traces 40a, 40b, 40c, 50a, 50b, 50c, respectively. The conductor traces 40a, 40b, 40c 50a, 50b, 50c of the first and second conductor layers 40, 50 extend in different directions, for example, transversely or perpendicularly relative to each other. The conductor traces 40a, 40b, 40c, 50a, 50b, 50c serve as electrodes for supplying voltage and/or current, in the thickness direction of the display element 2, through the emissive layer 10 and the DSD-layer 70 between the first and the second conductor layers 40, 50. The emissive layer 10 is configured to emit light in the emissive areas upon electrical current flowing through the emissive layer 10 between the first and the second conductor layers 40, 50.

The conductor traces 40a, 40b, 40c, 50a, 50b, 50c form the first and second conductor elements of the display element 2.

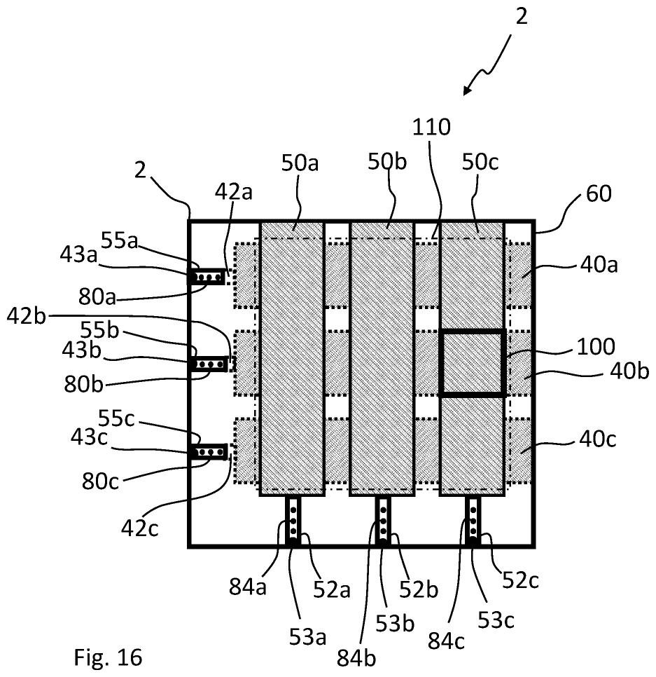

The conductor traces 40a, 40b, 40c, 50a, 50b, 50c define the emissive areas 100 at the locations where the conductor traces 40a, 40b, 40c, 50a, 50b, 50c of the first and the second conductor layers 40, 50 intersect, as shown in FIG. 16. The display element 2 of FIGS. 10 to 17 thereby forms a matrix type display element 2 with emissive pixels formed at those intersections 100.

In other embodiments, first and second conductor layers 40, 50 may be patterned in another way so as to have conductor patterns different from the conductor traces of the example of FIGS. 12 to 17.

In the context of the present application, emissive areas are defined to exist at locations where there are electrodes or conductor elements formed by conductor patterns present in both conductor layers, meaning directly opposite to each other on both side of the DSD-layer 70.

Further, it should be noted that all the above mentioned disclosed in connection with FIGS. 1 to 11 apply also to the embodiment and matrix display element of FIGS. 12 to 17 such that the conductor traces 40a, 40b, 40c, 50a, 50b, 50c correspond the first and second conductor elements 40d an 50d.

FIG. 12 shows a first cross-sectional view of the stacked structure of the matrix display element 2 along a second direction. The first conductor layer 40 comprises first conductor traces 40a, 40b, 40c extending in the first direction in the display element 2. FIG. 13 shows a second cross-sectional view of the stacked structure of the matrix display element 2 along the first direction. The second conductor layer 50 comprises second conductor traces 50a, 50b, 50c extending in the second direction in the display element 2. The first direction is perpendicular or transverse to the second direction.

The DSD-layer 70, meaning the first and second dielectric layers 20, 30 and the emissive layer 10, are provided between the first and second conductor layers 40, 50.

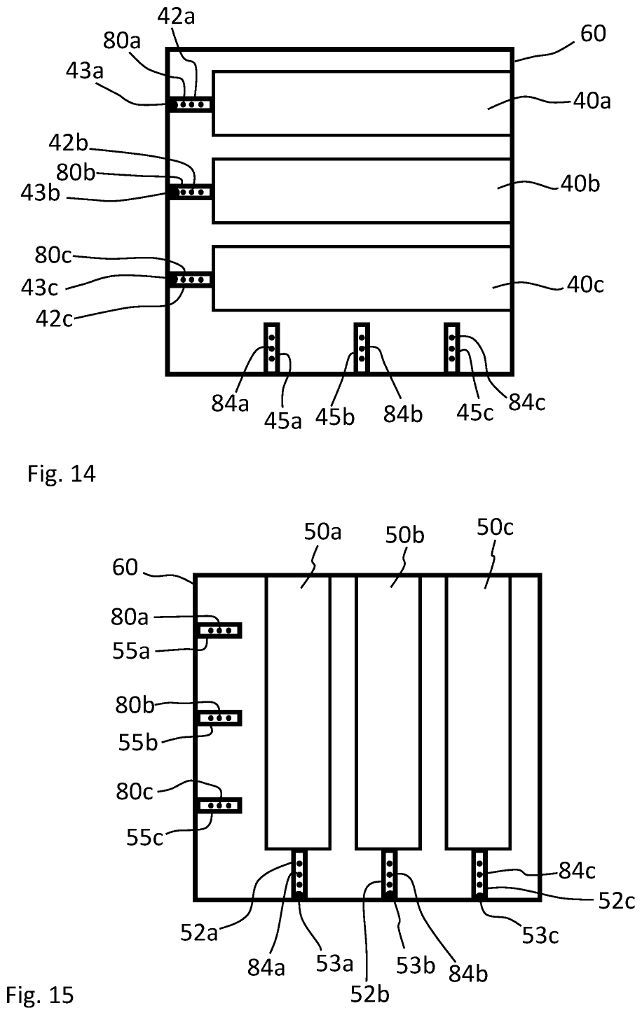

FIG. 14 shows the display element 2 according to the present invention. FIG. 14 shows the first conductor layer 40 with the first conductor traces 40a, 40b, 40c extending in the first direction. A separate first active electrical lead 42a, 42b, 42c is provided to the first conductor layer 40 and connected respectively to each of the first conductor traces 40a, 40b, 40c. The first active electrical leads 42a, 42b, 42c are provided or connected to an electrical connector or a first electrical pad 43a, 43b, 43c via which the electrical current is provided to/from the first active electrical leads 42a, 42b, 42c.

The first electrical leads 42a, 42b, 42c correspond the first electrical lead 42d of the display element of FIG. 6.

In the display element of FIG. 14, the first conductor layer 40 further comprises second passive electrical leads 45a, 45b, 45c. The second passive electrical leads 45a, 45b, 45c are separate passive electrical leads. Thus, the second passive electrical leads 45a, 45b, 45c are separate from the first conductor traces 40a, 40b, 40c and from the first active electrical leads 42a, 42b, 42c. Accordingly, the second passive electrical leads 45a, 45b, 45c are disconnected from the first conductor traces 40a, 40b, 40c and from the first active electrical leads 42a, 42b, 42c. Further, the second passive electrical leads 45a, 45b, 45c are not connected to electricity or power supply.

Further, one or more first electrical through leads 80a, 80b, 80c extend between the first conductor layer 40 and the second conductor layer 50 through the DSD-layer 70. The one or more first electrical through leads 80a, 80b, 80c are arranged in connection with the first active electrical leads 42a, 42b, 42c and arranged to provide electrical connection between the first active electrical leads 42a, 42b, 42c and the second conductor layer 50. Thus, the one or more first electrical through leads 80a, 80b, 80c are provided to the first active electrical leads 42a, 42b, 42c and arranged to extend from the first active electrical lead 42a, 42b, 42c to the second conductor layer 50 through DSD-layer 70.

The display element 2 of FIG. 14 is also provided with one or more second electrical through leads 84a, 84b, 84c extending between the first conductor layer 40 and the second conductor layer 50 through the DSD-layer 70. The one or more second electrical through leads 84a, 84b, 84c are arranged in connection with the second passive electrical leads 45a, 45b, 45c and arranged to provide electrical connection between the second passive electrical leads 45a, 45b, 45c and the second conductor layer 50. Thus, the one or more second electrical through leads 84a, 84b, 84c are provided to the second passive electrical lead 45a, 45b, 45c and arranged to extend from the second passive electrical leads 45a, 45b, 45c to the second conductor layer 50 through DSD-layer 70.

FIG. 15 shows the display element 2 according to the present invention and the second conductor layer 50 of the display element of FIG. 14. FIG. 15 shows the second conductor layer 50 with the second conductor traces 50a, 50b, 50c extending in the second direction. A separate second active electrical lead 52a, 52b, 52c is provided to the second conductor layer 50 and connected respectively to each of the second conductor traces 50a, 50b, 50c. The second active electrical leads 52a, 52b, 52c are provided or connected to an electrical connector or a second electrical pad 53a, 53b, 53c via which the electrical current is provided to/from the second active electrical leads 52a, 52b, 52c.

The second electrical leads 52a, 52b, 52c correspond the first electrical lead 52d of the display element of FIG. 7.

In the display element of FIG. 15, the second conductor layer 50 further comprises first passive electrical leads 55a, 55b, 55c. The first passive electrical leads 55a, 55b, 55c are separate passive electrical leads. Thus, the first passive electrical leads 55a, 55b, 55c are separate from the second conductor traces 50a, 50b, 50c and from the second active electrical leads 52a, 52b, 52c. Accordingly, the first passive electrical leads 55a, 55b, 55c are disconnected from the second conductor traces 50a, 50b, 50c and from the second active electrical leads 52a, 52b, 52c. Further, the first passive electrical leads 55a, 55b, 55c are not connected to electricity or power supply.

Further, the one or more second electrical through leads 84a, 84b, 84c extend between the first conductor layer 40 and the second conductor layer 50 through the DSD-layer 70. The one or more second electrical through leads 84a, 84b, 84c are arranged in connection with the second active electrical leads 52a, 52b, 52c and arranged to provide electrical connection between the second active electrical leads 52a, 52b, 52c and the second conductor layer 50. Thus, the one or more second electrical through leads 84a, 84b, 84c are provided to the second active electrical leads 52a, 52b, 52c and arranged to extend from the second active electrical leads 52a, 52b, 52c to the first conductor layer 40 through DSD-layer 70.

The display element 2 of FIG. 15 is also provided with one or more first electrical through leads 80a, 80b, 80c extending between the first conductor layer 40 and the second conductor layer 50 through the DSD-layer 70. The one or more first electrical through leads 80a, 80b, 80c are arranged in connection with the first passive electrical leads 55a, 55b, 55c and arranged to provide electrical connection between the first passive electrical leads 55a, 55b, 55c and the first conductor layer 50. Thus, the one or more first electrical through leads 80a, 80b, 80c are provided to the first passive electrical lead 55a, 55b, 55c and arranged to extend from the first passive electrical leads 55a, 55b, 55c to the first conductor layer 40 through DSD-layer 70.

The first and second electrical through leads 80a, 80b, 80c, 84a, 84, 84b correspond the first and second electrical through leads 80d, 84d of FIGS. 6 to 11.

FIG. 16 shows a schematic top view of the display element 2 of the matrix display and the FIGS. 14 and 15 as combined.

As shown in FIG. 16, the emissive areas 100 are formed to intersections of the first and second conductor traces 40a, 40b, 40c, 50a, 50b, 50c as the electricity may flow between the first and second conductor traces 40a, 40b, 40c, 50a, 50b, 50c through the DSD-layer 70 and the emissive layer 10.

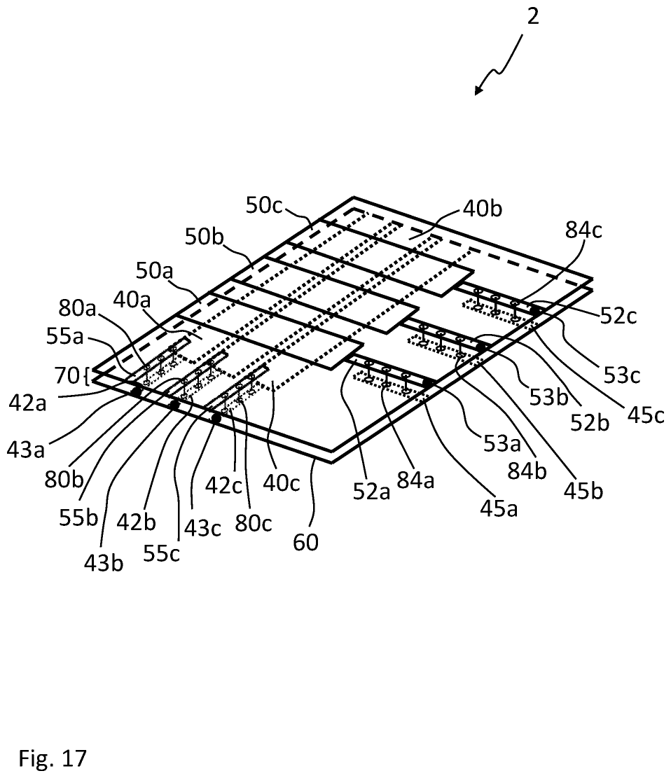

FIG. 17 shows schematically an axonometric view of the display element 2, and the layered structure thereof, of FIGS. 14 and 15. The display element 2 of FIG. 17 also substantially corresponds the display element 2 of FIGS. 5 and 8. As shown in FIG. 17, the first active conductor traces 40a, 40b, 40c of the first conductor layer 40 and the second active conductor traces 50a, 50b, 50c of the second conductor layer 50 are arranged to extend in the first and second direction perpendicularly to each other. Thus, electrical current may flow between the first and second active conductor 40a, 40b, 40c, 50a, 50b, 50c through the DSD-layer 70 in the intersecting emissive areas 100 such that the emissive layer 10 in the DSD-layer can emit light.

Further, the first active electrical leads 42a, 42b, 42c and the second active electrical leads 52a, 52b, 52c are not superposed relative to each other or opposite to each other. Thus, the first active electrical leads 42a, 42b, 42c and the second active electrical lead 52a, 52b, 52c arranged displaced relative to each other. Therefore, electrical current does not flow through DSD-layer 70 in the location of the first active electrical leads 42a, 42b, 42c and the second active electrical leads 52a, 52b, 52c.

However, the first active electrical leads 42a, 42b, 42c in the first conductor layer 40 and the first passive electrical leads 55a, 55b, 55c in the second conductor layer 50 are superposed relative to each other or directly opposite to each other on opposite sides of the DSD-layer 70. Further, the one or more first electrical through leads 80a, 80b, 80c are arranged to extend between the first conductor layer 40 and the second conductor layer 50 through the DSD-layer 70 and further between the first active electrical leads 42a, 42b, 42c and the first passive electrical leads 55a, 55b, 55c. Thus, the one or more first electrical through leads 80a, 80b, 80c are arranged to provide electrical connection between the first active electrical leads 42a, 42b, 42c and the first passive electrical leads 55a, 55b, 55c through the DSD-layer 70. Accordingly, the one or more first electrical through leads 80a, 80b, 80c are arranged in connection with the first passive electrical leads 55a, 55b, 55c and the first active electrical leads 42a, 42b, 42c.

Therefore, the one or more first electrical through leads 80a, 80b, 80c are connected to the first passive electrical leads 55a, 55b, 55c and the first active electrical leads 42a, 42b, 42c, respectively.

Further, the second active electrical leads 52a, 52b, 52c in the second conductor layer 50 and the second passive electrical leads 45a, 45b, 45c in the first conductor layer 40 are superposed relative to each other or directly opposite to each other on opposite sides of the DSD-layer 70. Further, the one or more second electrical through leads 84a, 84b, 84c are arranged to extend between the first conductor layer 40 and the second conductor layer 50 through the DSD-layer 70 and further between the second active electrical leads 52a, 52b, 52c and the second passive electrical leads 45a, 45b, 45c. Thus, the one or more second electrical through leads 84a, 84b, 84c are arranged to provide electrical connection between the second active electrical leads 52a, 52b, 52c and the second passive electrical leads 45a, 45b, 45c through the DSD-layer 70. Accordingly, the one or more second electrical through leads 84a, 84b, 84c are arranged in connection with the second passive electrical leads 45a, 45b, 45c and the second active electrical leads 52a, 52b, 52c.

Therefore, the one or more second electrical through leads 84d are connected to the second passive electrical leads 45a, 45b, 45c and the second active electrical lead 52a, 52b, 52c.

In FIG. 17, the first and second conductor layer 40, 50 and the DSD-layer 70 are on the substrate 60.

Further, it should be noted that the first or second passive electrical lead(s) 45a, 45b, 45c, 55a, 55b, 55c and the first or second electrical through leads 80a, 80b, 80c, 84a, 84b, 84c, respectively, may be omitted. Accordingly, the passive electrical leads may be provided only in connection with either the first or the second conductor layer 40, 50.

Accordingly, the first and second conductor layers 40, 50 and thus the first and second dielectric layers 20, 30 may be reversible in the context of this application.

The present invention also provides a method for manufacturing a transparent thin film electroluminescent display element 2 having an emissive area. The method comprises forming, on a transparent substrate 60, the stacked structure of the display element 2. Forming said stacked structure comprises the first step of providing, the first conductor layer 40 on the substrate 60 by an appropriate deposition method. The first step comprises providing one or more first active conductor elements 40d, 40a, 40b, 40c and one or more first active electrical leads 42d, 42a, 42b, 42c for each of the first active conductor elements 40d, 40a, 40b, 40c, respectively.

In the second step, the first dielectric layer 20 is provided on the first conductor layer 40 by an appropriate deposition method.

Then in the third step, the emissive layer 10 is provided on the first dielectric layer 20, by an appropriate deposition method.

Further, in the fourth step, the second dielectric layer 30 is provided on the emissive layer 10 by an appropriate deposition method.

Then, in the fifth step, the second conductor layer 50 is formed on the second dielectric layer 30 by an appropriate deposition method. The fifth step comprises providing one or more second active conductor elements 50d, 50a, 50b, 50c and one or more second active electrical leads 52d, 52a, 52b, 52c for each of the second active conductor elements 50d, 50a, 50b, 50c, respectively.

According to the present invention, the fifth step also comprises providing to the second conductor layer 50 the one or more first passive electrical leads 55d, 55a, 55b, 55c. The first passive electrical lead 55d, 55a, 55b, 55c being separate from the second active conductor element 50d, 50a, 50b, 50c and provided opposite the first active electrical leads 42d, 42a, 42b, 42c in the first conductor layer 40.

The method further comprises an additional step carried out before the fifth step and after the fourth step. Thus, the additional step is carried out between the fourth and fifth steps. The additional step comprises forming one or more first through holes 80d, 80a, 80b, 80c through first and second dielectric layers 20, 30 and the emissive layer 10 in the locations or areas of the first active electrical leads 42d, 42a, 42b, 42c.

The one or more first through holes 80d, 80a, 80b, 80c are formed from the direction of the DSD-layer towards the first active electrical leads 42d, 42a, 42b, 42c in the first conductor layer 40.

The one or more first through holes 80d, 80a, 80b, 80c are formed to extends through the DSD-layer up to the first active electrical leads 42d, 42a, 42b, 42c in the thickness direction of the stacked structure. However, the one or more first through holes 80d, 80a, 80b, 80c do not penetrate through the first active electrical leads 42d, 42a, 42b, 42c.

In one embodiment, the additional step comprises forming the one or more first through holes by laser cutting, or forming the one or more first through holes 80d, 80a, 80b, 80c by using laser pulses.

The penetration depth of the laser may be adjusted by adjusting or utilizing a laser lens in connection with a laser device. The penetration depth of the laser may also be adjusted by choosing or adjusting the wave length of the laser. Laser is preferable cutting method, as it may form holes of predetermined depth in the know material and also the it may provide very tiny holes with tiny diameter. These tiny holes may be substantially invisible to human eye such that the transparency of display element is not compromised.

When, the fifth step is performed after the additional step, the one or more first through holes 80d, 80a, 80b, 80c are filled with the deposited material of the second conductor layer 50. The first passive electrical leads 55d, 55a, 55b, 55d are formed to the second conductor layer 50 on the locations opposite the first active electrical leads 42d, 42a, 42b, 42c in the first conductor layer 40. As also the one or more first through holes 80d, 80a, 80b, 80c are formed in the locations or areas of the first active electrical leads 42d, 42a, 42b, 42c, the material of the second conductor layer 50 enters the one or more first through holes 80d, 80a, 80b, 80c and fills them when the first passive electrical leads 55d, 55a, 55b, 55d are formed with the deposition method. Thus, electrical connection between the first active electrical leads 42d, 42a, 42b, 42c and the first passive electrical leads 55d, 55a, 55b, 55d is formed during the fifth step.

The first method step may also comprise also comprises providing to the first conductor layer 40 the one or more second passive electrical leads 45d, 45a, 45b, 45c. The second passive electrical leads 45d, 45a, 45b, 45c being separate from the first active conductor element 40d, 40a, 40b, 40c. Thus, in the fifth step the second active electrical leads 52d, 52a, 52b, 52c are formed to the locations/areas of the second passive electrical leads 45d, 45a, 45b, 45c.

Further, the additional step comprises forming the one or more second through holes 84d, 84a, 84b, 84c through first and second dielectric layers 20, 30 and the emissive layer 10 in the locations or areas of the second passive electrical leads 45d, 45a, 45b, 45c. The one or more second through holes 84d, 84a, 84b, 84c are formed similarly as the first the one or more first through holes 80d, 80a, 80b, 80c.

Then as the fifth step is performed after the additional step, the one or more second through holes 84d, 84a, 84b, 84c are filled with the deposited material of the second conductor layer 50. The second active electrical leads 52d, 52a, 52b, 52d are formed to the second conductor layer 50 on the locations opposite the second passive electrical leads 45d, 45a, 45b, 45c in the first conductor layer 40. As also the one or more second through holes 84d, 84a, 84b, 84c are formed in the locations or areas of the second passive electrical leads 45d, 45a, 45b, 45c, the material of the second conductor layer 50 enters the one or more second through holes 84d, 84a, 84b, 84c and fills them when the second active electrical leads 52d, 52a, 52b, 52d are formed with the deposition method. Thus, electrical connection between the second active electrical leads 52d, 52a, 52b, 52c and the second passive electrical leads 45d, 45a, 45b, 45d is formed during the fifth step.

In some embodiments, the first and fifth steps are carried out by sputtering and the second, third and fourth steps are carried out by utilizing atomic layer deposition.

Further, the in first and fifth steps the first and second conductor layers 40, 50 are formed of indium tin oxide, ITO.

The invention has been described above with reference to the examples shown in the figures. However, the invention is in no way restricted to the above examples but may vary within the scope of the claims.

1. A transparent thin film electroluminescent display element with an emissive area, the display element having a layer stack in the emissive area comprising:
a first conductor layer having a first active conductor element;
a second conductor layer having a second active conductor element; and
an emissive layer superposed between the first and second conductor layers arranged to emit light in the emissive area upon electrical current flowing through the emissive layer between the first active conductor element and the second active conductor elements; and
a first dielectric layer provided between the first conductor layer and the emissive layer and a second dielectric layer provided between the second conductor layer and the emissive layer, and that
the first conductor layer comprises a first active electrical lead connected to the first active conductor element and arranged to provide electrical connection to the first active conductor element,
wherein:
the second conductor layer comprises a first passive electrical lead, the first passive electrical lead being separate from the second active conductor element; and
one or more first electrical through leads extending between the first active electrical lead and the first passive electrical lead through the first and second dielectric layers and the emissive layer, the one or more first electrical through leads being arranged to provide electrical connection between the first active electrical lead and the first passive electrical lead through the first and second dielectric layers and the emissive layer.

2. A transparent thin film electroluminescent display element according to claim 1, wherein:
the second conductor layer comprises a second active electrical lead connected to the second active conductor element and arranged to provide electrical connection to the second active conductor element;
the first conductor layer comprises a second passive electrical lead, the second passive electrical lead being separate from the first active conductor element; and
one or more second electrical through leads extending between the second active electrical lead and the second passive electrical lead through the first and second dielectric layers and the emissive layer, the one or more second electrical through leads being arranged to provide electrical connection between the second active electrical lead and the second passive electrical lead through the first and second dielectric layers and the emissive layer.

3. A transparent thin film electroluminescent display element according to claim 2, wherein:
the display element comprises one or more first through holes extending between the first active electrical lead and the first passive electrical lead through the first and second dielectric layers and the emissive layer; or
the display element comprises one or more first through holes extending between the first active electrical lead and the first passive electrical lead through the first and second dielectric layers and the emissive layer, and one or more second through holes extending between the second active electrical lead and the second passive electrical lead through the first and second dielectric layers and the emissive layer.

4. A transparent thin film electroluminescent display element according to claim 3, wherein:
the one or more first through holes extending through the first and second dielectric layers and the emissive layer are laser cut holes; or
the one or more first through holes and the one or more second through holes extending through the first and second dielectric layers and the emissive layer are laser cut holes.

5. A transparent thin film electroluminescent display element according to claim 3, wherein:
the one or more first through holes are provided with electrically conductive material and arranged to provide electrical connection between the first active electrical lead and the first passive electrical lead; or
the one or more first through holes and the one or more second through holes are provided with electrically conductive material and arranged to provide electrical connection between the first active electrical lead and the first passive electrical lead and between the second active electrical lead and the second passive electrical lead.

6. A transparent thin film electroluminescent display element according to claim 3, wherein:
the one or more first through holes are provided with same material as the first active conductor element or the second active conductor element or the first and the second active conductor elements; or
the one or more first through holes and the one or more second through holes are provided with same material as the first active conductor element or the second active conductor element or the first and second active conductor elements.

7. A transparent thin film electroluminescent display element according to claim 1, wherein the first active conductor element or the second active conductor element are made of one of the following materials indium tin oxide.

8. A transparent thin film electroluminescent display element according to claim 2, wherein:
the first active electrical lead and the first passive electrical lead are arranged opposite to each other in the first conductor layer and in the second conductor layer, respectively; or
the first active electrical lead and the first passive electrical lead are arranged opposite to each other in the first conductor layer and in the second conductor layer, respectively; and
the second active electrical lead and the second passive electrical lead are arranged opposite to each other in the first conductor layer and in the second conductor layer, respectively.

9. A transparent thin film electroluminescent display element according to claim 1, wherein the display element is a segment display element comprising two or more first active conductor elements (40d) and two or more first active electrical leads (42d), respectively, in the first conductor layer, and two or more second active conductor elements (50d) and two or more second active electrical leads (52d), respectively, in the second conductor layer, and that:
the second conductor layer comprises two or more first passive electrical leads (55d) arranged opposite to the two or more first active electrical leads (42d) in the first conductor layer; and
one or more first electrical through leads (80d) are arranged to extend between each respective first active electrical lead (42d) and first passive electrical lead (55d) through the first and second dielectric layers and the emissive layer; or
the second conductor layer comprises two or more first passive electrical leads (55d) arranged opposite to the two or more first active electrical leads (42d) in the first conductor layer;
one or more first electrical through leads (80d) are arranged to extend between each respective first active electrical lead (42d) and first passive electrical lead (55d) through the first and second dielectric layers and the emissive layer;
the first conductor layer comprises two or more second passive electrical leads (45d) arranged opposite to the two or more second active electrical leads (52d) in the second conductor layer; and
one or more second electrical through leads (84d) are arranged to extend between each respective second active electrical lead (52d) and second passive electrical lead (45d) through the first and second dielectric layers and the emissive layer.

10. A transparent thin film electroluminescent display element according to claim 1, wherein the display element is matrix display element comprising two or more first active conductor traces (40a, 40c) and two or more first active electrical leads (42a, 42b, 42c) connected to the two or more first active conductor traces (40a, 40b, 40c), respectively, in the first conductor layer, and two or more second active conductor traces (50a, 50b, 50c) and two or more second active electrical leads (52a, 52b, 52c) connected to the two or more second active conductor traces (50a, 50c), respectively, in the second conductor layer, and that:
the second conductor layer comprises two or more first passive electrical leads (55a, 55b, 55c) arranged opposite to the two or more first active electrical leads (42a, 42b, 42c) in the first conductor layer; and
one or more first electrical through leads (80a, 80b, 80c) are arranged to extend between each respective first active electrical lead (42a, 42b, 42c) and first passive electrical lead (55a, 55b, through the first and second dielectric layers and the emissive layer; or
the second conductor layer comprises two or more first passive electrical leads (55a, 55b, 55c) arranged opposite to the two or more first active electrical leads (42s, 42b, 42c) in the first conductor layer;
one or more first electrical through leads (80a, 80b, 80c) are arranged to extend between each respective first active electrical lead (42a, 42b, 42c) and first passive electrical lead (55a, 55b, 55c) through the first and second dielectric layers and the emissive layer;
the first conductor layer comprises two or more second passive electrical leads (45a, 45b, 45c) arranged opposite to the two or more second active electrical leads (52a, 52b, 52c) in the second conductor layer; and
one or more second electrical through leads (84a, 84b, 84c) are arranged to extend between each respective second active electrical lead (52a, 52b, 52c) and second passive electrical lead (45a, 45b, 45c) through the first and second dielectric layers and the emissive layer.

11. A method for manufacturing a transparent thin film electroluminescent display element having an emissive area, the method comprising:
a) providing a first conductor layer, the first conductor layer comprising a first active conductor element and a first active electrical lead connected to the first active conductor element for providing electrical connection to the first active conductor element;
b) providing a first dielectric layer on the first conductor layer;
c) providing an emissive layer on the first dielectric layer;
d) providing a second dielectric layers on the emissive layer; and
e) providing a second conductor layer on the second dielectric layer, the second conductor layer comprising a second active conductor element and a second active electrical lead connected to the second active conductor element for providing electrical connection to the second active conductor element,
the emissive layer emitting light in the emissive area upon electrical current flowing through the emissive layer between the first active conductor element and the second active conductor element,
wherein:
the step e) further comprises providing to the second conductor layer a first passive electrical lead, the first passive electrical lead being separate from the second active conductor element; and
the method further comprises step f) providing electrical connection between the first active electrical lead and the first passive electrical lead through the first and second dielectric layers and the emissive layer.

12. A method according to claim 11, wherein:
the step a) further comprises providing to the first conductor layer a second passive electrical lead, the second passive electrical lead being separate from the first active conductor element; and
the method further comprises step g) providing electrical connection between the second active electrical lead and the second passive electrical lead through the first and second dielectric layers and the emissive layer.

13. A method according to claim 12, wherein:
the step f) comprises forming one or more first through holes through first and second dielectric layers and the emissive layer and providing electrically conductive material to the one or more first through holes for providing electrical connection between the first active electrical lead and the first passive electrical lead; or
the step f) comprise forming one or more first through holes through first and second dielectric layers and the emissive layer and providing electrically conductive material to the one or more first through holes for providing electrical connection between the first active electrical lead and the first passive electrical lead; and
the step g) comprise forming one or more second through holes through first and second dielectric layers and the emissive layer and providing electrically conductive material to the one or more second through holes for providing electrical connection between the second active electrical lead and the second passive electrical lead.

14. A method according to claim 13, wherein:
the step f) comprises forming the one or more first through holes by laser cutting; or
the step f) comprises forming the one or more first through holes by using laser pulses;
the steps f) and g) comprise forming the one or more first through holes and the one or more second through holes by laser cutting; or
the steps f) and g) comprise forming the one or more first through holes and the one or more second through holes by using laser pulses.

15. A method according to claim 14, wherein:
the method comprises carrying out first the steps a), b), c) and d), and then carrying out step f) by forming the one or more first through holes in connection with the first active electrical lead; and
the method further comprises carrying out the step e) after the step d), the step e) comprises utilizing a material deposition method for providing the second conductor layer from an electrically conductive deposition material and the step f) comprises filling the one or more first through holes with the electrically conductive deposition material during step e) upon providing the first passive electrical lead; or
the method comprises carrying out first the steps a), b), c) and d), and then carrying out step f) by forming the one or more first through holes in connection with the first active electrical lead and step g) by forming the one or more second through holes in connection with the second passive electrical lead; and
the method further comprises carrying out the step e) after the steps f) and g), the step e) comprises utilizing a material deposition method for providing the second conductor layer from an electrically conductive deposition material, the step f) comprises filling the one or more first through holes with the electrically conductive deposition material during step e) upon providing the first passive electrical lead, and the step g) comprises filling the one or more second through holes with the electrically conductive deposition material during step e) upon providing the second active electrical lead.

16. A method according to claim 11, wherein:
steps a) and e) comprise providing the first and second conductor layers from indium tin oxide; or
steps a) and e) comprise providing the first and second conductor layers from indium tin oxide by sputtering.
